(19) United States
(12) Patent Application Publication
(10) Pub. No.: US 2025/0259895 A1
(43) Pub. Date: Aug. 14, 2025

(54) METAL SIGNAL OR POWERLINE SEPARATION THROUGH SELECTIVE DEPOSITION IN ADVANCED MEMORY DEVICES

(71) Applicant: Applied Materials, Inc., Santa Clara, CA (US)

(72) Inventors: Zhijun Chen, San Jose, CA (US); Fredrick Fishburn, Belmont, CA (US); Raghuveer S. Makala, Campbell, CA (US); Balasubramanian Pranatharthiharan, San Jose, CA (US)

(73) Assignee: Applied Materials, Inc., Santa Clara, CA (US)

(21) Appl. No.: 18/438,146

(22) Filed: Feb. 9, 2024

(51) Int. Cl. H01L 21/768; H01L 21/02; H01L 21/67; H10B 12/00

(52) U.S. Cl. CPC H01L 21/76885; H01L 21/0228; H01L 21/67167; H01L 21/76834; H10B 12/03

(57) ABSTRACT

The present technology includes methods and systems for forming advanced memory structures, and the resulting devices. Methods include forming a dielectric material layer over a first sidewall, a second sidewall, and a bottom wall, of one or more features, where the first sidewall is spaced apart from the second sidewall and the bottom wall is disposed between the first sidewall and the second sidewall. Methods include depositing a liner material directly on the dielectric material layer on the first sidewall, the second sidewall, and the bottom wall. Methods include removing at least a portion of the liner material from the bottom wall. Methods include selectively depositing a conductive material on a remaining portion of the liner material.

### TECHNICAL FIELD

This disclosure generally describes designs for advanced memory devices, such as 4F² dynamic random access memory (DRAM) arrays, 6F² DRAM arrays, 3D DRAM, 3D NAND, junction-less SONOS memory, floating body cell memory, oxide semiconductor memory, ferroelectric memory, and other devices having high aspect ratio features. More specifically, this disclosure describes advanced memory arrays with low signal or power line resistivity.

### BACKGROUND

With advances in computing technology, computing devices are smaller and have increased processing power. Accordingly, increased storage and memory is needed to meet the devices' programming and computing needs. The shrinking size of the devices with increased storage capacity is achieved by increasing the number of storage units having smaller geometries.

Dynamic random-access memory (DRAM) architectures continue to scale down over time. For example, a one transistor, one capacitor (1T-IC) DRAM cell architecture has successfully scaled down from an 8F² size to a 6F² size (where F is the minimum feature size). Further design scheme changes from 6F² to 4F² may help further improve area density. As devices continue to scale down, there is a desire to improve the resistivity of the device. However, advanced design schemes often exhibit high aspect ratio features, making etching and deposition of conductive materials difficult to conduct without damaging the device. Thus, there is a need in the industry to improve one or more features of advanced memory devices.

### BRIEF SUMMARY

The present technology is generally directed to methods of forming an advanced memory device. Methods include forming a dielectric material layer over a first sidewall, a second sidewall, and a bottom wall, of one or more features, where the first sidewall is spaced apart from the second sidewall and the bottom wall is disposed between the first sidewall and the second sidewall. Methods include depositing a liner material directly on the dielectric material layer on the first sidewall, the second sidewall, and the bottom wall. Methods include removing at least a portion of the liner material from the bottom wall. Methods include selectively depositing a conductive material on a remaining portion of the liner material.

In embodiments, the liner material is deposited conformally on the first sidewall and the second sidewall. Moreover, in embodiments, the liner is deposited by atomic layer deposition, chemical vapor deposition, or a combination thereof. In further embodiments, the conductive material is deposited utilizing a selective atomic layer deposition process, a selective chemical vapor deposition process, or a combination thereof. Additionally or alternatively, the conductive material is only deposited over the liner material. Embodiments include depositing the liner material, etching the liner material, and depositing the conductive conductivity material are conducted without a vacuum break. Yet more embodiments include recessing the liner material. Furthermore, in embodiments, the conductive material is recessed with the liner material, or is selectively deposited after recessing the liner material. In embodiments, methods include filling the one or more features with a sacrificial material after depositing the liner material. Moreover, in embodiments, the etching of the liner material is conducted prior to filling the one or more features. In further embodiments, the liner material is recessed simultaneously or sequentially with the sacrificial material.

In more embodiments, liner material includes titanium nitride, titanium silicon nitride, titanium aluminide, titanium aluminum nitride, polycrystalline silicon, amorphous silicon, molybdenum nitride, molybdenum silicide, titanium, ruthenium, tungsten, molybdenum, tantalum nitride, tungsten nitride, tungsten silicide, tungsten carbon nitride, tungsten silicon nitride, niobium nitride, titanium aluminum nitride, titanium silicon nitride, tantalum silicon nitride, ruthenium titanium nitride, lanthanum nitride, or a combination thereof. In yet more embodiments, the conductive material comprises titanium nitride, titanium silicon nitride, polycrystalline silicon, molybdenum nitride, molybdenum silicide, titanium, tantalum, ruthenium, tungsten, molybdenum, platinum, nickel, cobalt, tantalum nitride, tungsten nitride, niobium nitride, titanium aluminide, titanium aluminum nitride, titanium silicide, titanium silicon nitride, tantalum silicide, tantalum silicon nitride, ruthenium titanium nitride, nickel silicide, cobalt silicide, iridium oxide, ruthenium oxide or a combination thereof, and combinations thereof. In embodiments, the conductive material comprises molybdenum, tungsten, or a combination thereof, and wherein the molybdenum and/or tungsten is selectively deposited by contacting the liner material with one or more molybdenum and/or tungsten precursors. Moreover, in embodiments, the one or more molybdenum precursors comprises molybdenum chloride, molybdenum oxychloride, a molybdenum based metal organic compound or a combination thereof, and/or the one or more tungsten precursors comprises tungsten chloride.

The present technology is also generally directed to advanced memory arrays. Arrays include a feature having a first sidewall opposed to a second sidewall, and a bottom wall. Arrays include a dielectric material layer formed over the first sidewall, second sidewall, and the bottom wall. Arrays include a liner formed over the dielectric material layer on the first sidewall, second sidewall and the bottom wall. Arrays include a conductive material formed over the liner on the first sidewall and the second sidewall, wherein the bottom wall is generally free of the conductive material, and wherein the conductive material formed over the liner on the first sidewall is electrically separated from the conductive material formed over the liner on the second sidewall. Arrays include where the conductive material is formed from molybdenum, ruthenium, tungsten, titanium nitride, titanium, or a combination thereof, and the liner is formed from titanium nitride, titanium silicon nitride, amorphous silicon, polycrystalline silicon, molybdenum nitride, molybdenum silicide, or a combination thereof.

The present technology is also generally directed to semiconductor processing systems. Systems include a system controller configured to form a dielectric material layer over a first sidewall, second sidewall, and a bottom wall of a feature, in a first processing chamber. Systems include a system controller configured to deposit a liner material over the dielectric material layer on the first sidewall, second sidewall, and bottom wall, in a second processing chamber. Systems include a system controller configured to etch the liner material from the bottom wall, in a third processing chamber, and selectively deposit a conductive material over the liner material, in the second processing chamber or in a fourth processing chamber. In embodiments, the second processing chamber, third processing chamber, and optional fourth processing chamber, are contained within a cluster tool having a shared vacuum environment. Moreover, in embodiments, systems include a further processing chamber comprising one or more oxide removal systems.

Such technology may provide numerous benefits over conventional systems and techniques. For example, the processes and systems may allow the use of difficult to etch materials in high aspect ratio features, such as word lines. Additionally, the processes and systems may significantly improve gate resistivity, by allowing the separation of high resistivity word line materials. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a top plan view of an exemplary processing chamber according to embodiments of the present technology.

FIG. 1B illustrates a top view of a conventional 4F² memory array.

FIG. 1C illustrates a perspective view of a conventional 4F² memory array.

FIG. 2 shows selected operations in a formation method according to embodiments of the present technology.

FIG. 3A shows a schematic view of a semiconductor structure according to embodiments of the present technology.

FIG. 3B shows a schematic view of a semiconductor structure according to embodiments of the present technology.

FIG. 3C shows a schematic view of a semiconductor structure according to embodiments of the present technology.

FIG. 3D shows a schematic view of a semiconductor structure according to embodiments of the present technology.

FIG. 4 shows selected operations in a formation method according to embodiments of the present technology.

FIG. 5A shows a schematic view of a semiconductor structure according to embodiments of the present technology.

FIG. 5B shows a schematic view of a semiconductor structure according to embodiments of the present technology.

FIG. 6 shows selected operations in a formation method according to embodiments of the present technology.

FIG. 7A shows a schematic view of a semiconductor structure according to embodiments of the present technology.

FIG. 7B shows a schematic view of a semiconductor structure according to embodiments of the present technology.

FIG. 7C shows a schematic view of a semiconductor structure according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Historically, DRAM chip bit densities have been increasing by approximately 25% node over node. However, the node over node increase in bit density has trended down to closer to 20% for the more recent generations, mainly due to the challenges with scaling the cell area. Cell design architecture for modern DRAM technology has been based on 6F² geometry, where “F” is the minimum feature size for a given technology node. Switching from 6F² to 4F² cell architecture could result in a 33% increase in bit density at the same technology node. In addition, patterning difficulties for 4F² DRAM are greatly reduced as compared to 6F². This is due at least in part to the fact that in the 4F² DRAM scheme, the capacitor and bit line are located at two ends of a vertical cell transistor, instead of tightly packed on the same side as in 6F² DRAM.

However, advanced memory structures, including vertical cell structures such as 4F² DRAM, 6F² DRAM, 3D NAND, 3D DRAM, junction-less SONOS memory, floating body cell memory, oxide semiconductor memory, ferroelectric memory, and other devices having high aspect ratio features, as examples, come with their own challenges. For example, such advanced memory cells exhibit high aspect ratio features with small critical dimensions, making directional etching difficult, particularly without damaging the surrounding sidewalls. For instance, there is a desire to utilize conductive materials in advanced memory devices, such as for forming signal or power lines, which may also be in the form of sheets. However, conductive materials, such as molybdenum, ruthenium, tungsten, titanium, and the like, are difficult to etch, particularly when placed in high aspect ratio structures. The etch difficulties are further compounded when the device requires little to no alteration of the physical and chemical properties of the conductive materials. This is problematic, as, when forming metallic signal or power lines, it is necessary to separate the deposited material in order to isolate the neighboring cells, which requires a bottom punch with a high bias reactive-ion etch. Furthermore, this problem is intensified in advanced memory structures, as the aspect ratio of the feature is from 25:1 up to 30:1 after deposition of the metallic signal or power line material. Thus, existing processes have failed to provide methods of forming electrically isolated conductive signal or power lines, such as wordlines or bitlines, in close vicinity without damaging the conductive material formed on the device sidewalls.

The present technology overcomes these and other problems by depositing a conformal liner material over the feature, and etching the bottom of the liner material prior to introduction of a conductive signal or power line material. Namely, if the liner material and conductive material are carefully selected, a liner material that has favorable etch characteristics may be utilized, decreasing the difficulty of the bottom punch process. Furthermore, the careful selection of the conductive material may allow for growth of the conductive material to occur only over the bottom punched liner material, restricting the growth of the conductive material to only portions of the feature having a liner formed thereon. In addition, the liner material may be deposited at a thickness that is less than 50% of a thickness necessary for the conductive material. Thus, the difficulty of the etch and likelihood of sidewall damage can be further decreased, as the bottom punch etching may occur when the feature exhibits a much lower aspect ratio, such as less than 30:1, less than 20:1, less than 15:1, or even less than 10:1, and a larger critical dimension. Thus, the present technology provides for the formation of metallic signal or power lines utilizing conductive materials in advanced memory structures, without etching the conductive material.

Although the remaining disclosure will routinely identify specific deposition and etch processes utilized for forming vertical cell access array transistors (VCAATs), such as a 4F² DRAM device, it will be readily understood that the systems and methods are equally applicable to other memory devices, including 6F² DRAM arrays, 3D NAND, and/or 3D DRAM device, junction-less SONOS memory, floating body cell memory, oxide semiconductor memory, ferroelectric memory, and other devices having high aspect ratio features, and orientations thereof, as well as processes for forming such devices. Accordingly, the technology should not be considered to be so limited as for use with these specific devices or systems alone. The disclosure will discuss one possible semiconductor device that may include one or more components, utilizing one or more word lines according to embodiments of the present technology before additional variations and adjustments to this apparatus according to embodiments of the present technology are described.

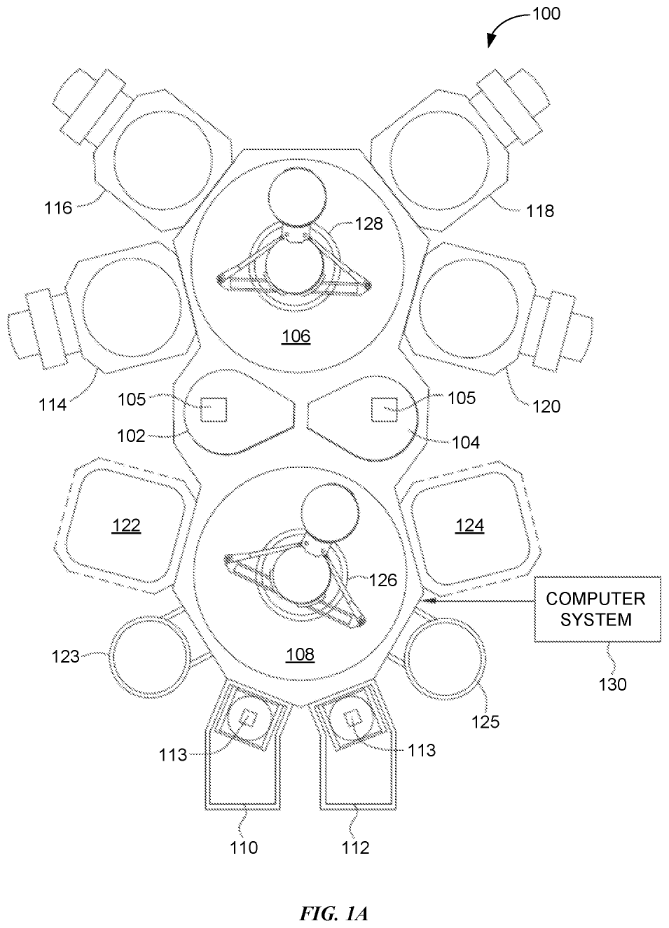

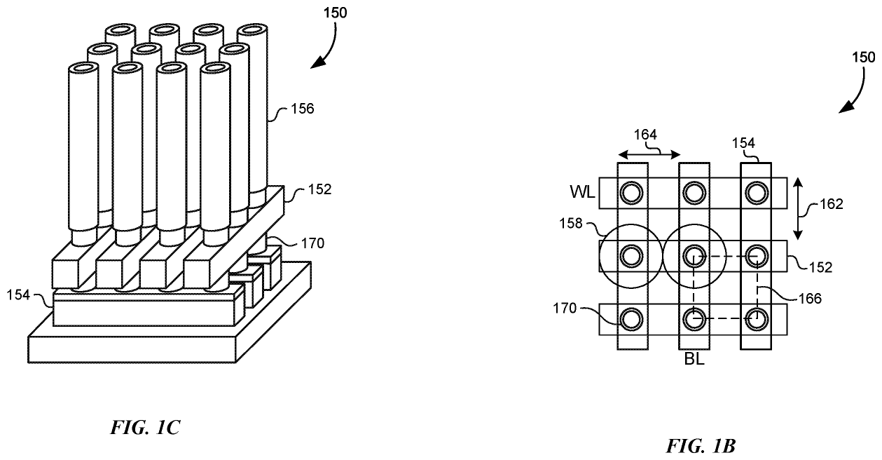

FIG. 1A illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108, and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

FIGS. 1B and 1C illustrate top and perspective views of a conventional 4F² memory array 150. The memory array 150 may include a plurality of word lines 152 that are arranged in a first layer over a substrate. The word lines 152 may be conductive traces that are used to select a word line of memory cells in the memory array 150. The memory array 150 may also include a plurality of bit lines 154 arranged in a second layer over a substrate. The plurality of bit lines may be conductive traces that are used to select a bit line of memory cells in the memory array 150. Activating one of the plurality of bit lines 154 and one of the plurality of word lines 152 may select an individual cell in the memory array 150. The first layer and the second layer may include different metal layers formed at different times during manufacturing process. For example, the first layer with the word lines 152 may be formed above the second layer with the bit lines 154 such that the two layers do not intersect.

A plurality of vertical memory cells may be arranged over intersections between the plurality of word lines 152 and the plurality of bit lines 154. Each of the plurality of vertical memory cells may include a vertical transistor, which may be referred to as a vertical pillar transistor or vertical column transistor. A channel material for the transistor may be formed from a single-crystal silicon pillar, or any other substrates discussed in greater detail below. This silicon channel may be formed by etching the substrate. Each of the plurality of vertical memory cells may also include a vertical capacitor 156. The vertical memory cell may operate by storing a charge on the vertical capacitors 156 to indicate a saved memory state. However, while FIGS. 1B and 1C illustrate the arrangement of the vertical transistors and capacitors in a rectangular generally orthogonal grid pattern (where “generally orthogonal” may be within about 100 from orthogonal, such as less than or about 7.5°, such as less than or about 5°, such as less than or about 2.5°, such as less than or about 1° from orthogonal, or any ranges or values therebetween, where “generally” may be utilized to similarly vary “vertical”, “horizontal” and the like), it should be understood that other orientations are contemplated for use with the present technology. For instance, in embodiments, the capacitors and vertical transistors may be spaced in alternating rows that are offset by one half the distance between the vertical transistors. Namely, a first row of memory cells may be regularly spaced apart in a line in a first direction, and a second row of memory cells may also be regularly spaced apart in a line also in the first direction, but the second row of memory cells may be offset from the first row of memory cells, such as aligned approximately halfway between the vertical transistors and capacitors of the first row, in embodiments. Such a pattern may be referred to as a “honeycomb” or “hexagonal pattern” as compared to the square pattern illustrated in FIGS. 1B and 1C. Thus, it should be understood that any suitable orientation may be utilized with the present technology.

It is useful to characterize the dimensions of the unit cell area 166 for this conventional 4F²memory array for comparison to the simple memory array described below. For example, a capacitor footprint 158 may be defined as a circular area around each vertical capacitor 156. The capacitor footprint 158 may include the horizontal cross-sectional area of the capacitor expanded out until the cross-sectional area contacts a capacitor area from a neighboring memory cell. Assuming that the word line pitch 162 for the plurality of word lines 152 and the bit line pitch 164 for the plurality of bit lines 154 may be defined as 2F. This leads to an overall cross-sectional area of 4F² for a unit cell area 166.

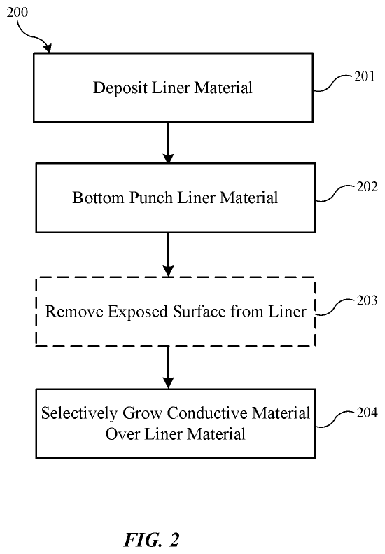

FIG. 2 shows exemplary operations in a method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. In addition, while the method may describe the formation method vertically, it should be understood that the other orientation from bit line to word line side may be utilized.

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support/transfer platform, which may be a pedestal such as substrate support 104, and which may reside in a processing region of the chamber, such as processing region of processing chamber 120 described above. Method 200 describes operations shown schematically in the Figures, the illustrations of which will be described in conjunction with the operations of method 200. It is to be understood that the Figures illustrate only partial schematic views, and a semiconductor substrate may include further components as illustrated in the figures, as well as alternative components, of any size or configuration that may still benefit from aspects of the present technology.

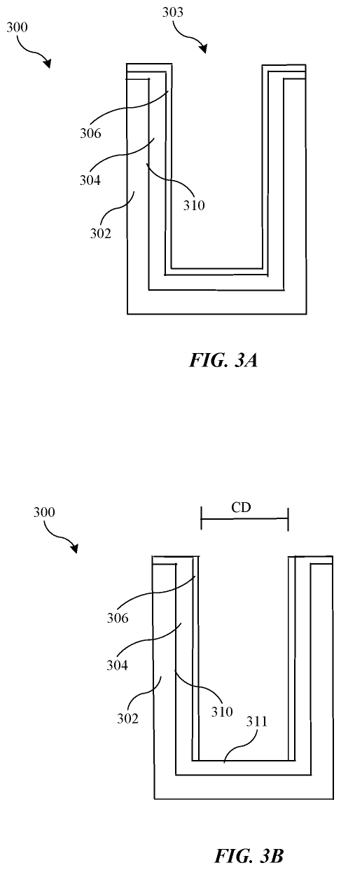

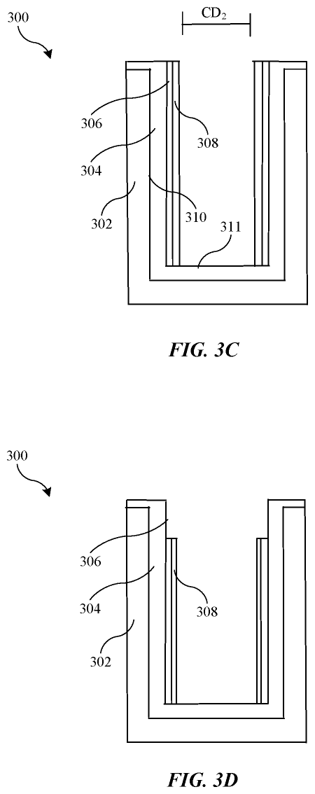

Method 200 may or may not involve optional operations to develop the semiconductor structure to a particular fabrication operation. It is to be understood that method 200 may be performed on any number of semiconductor structures 300 as illustrated in the Figures, including exemplary structures on which a selective deposition material may be formed. As illustrated in FIG. 3A semiconductor structure formed from a substrate material, which may be any number of materials, such as a base wafer or substrate made of silicon or silicon-containing materials, germanium, silicon germanium (SiGe), silicon on insulator (SOI), silicon germanium on insulator (SGOI), indium antimonide, lead telluride compounds, indium arsenide, indium phosphide, gallium arsenide, other substrate materials, as well as one or more materials that may be formed overlying the substrate during semiconductor processing.

Moreover, while various deposition and fill processes will be described, it should be understood that, in embodiments, the semiconductor structure may be transferred to and between one or more process chambers 114, 116, 118, 120, 122, and 124 configured for deposition and/or fill processes, including chambers for: chemical vapor deposition (CVD), physical vapor deposition (PVD), atomic layer deposition (ALD), thermally enhanced chemical vapor deposition (CVD), plasma-enhanced chemical vapor deposition (PECVD), plasma enhanced atomic layer deposition (PEALD), or the like. Thus, unless specified, it should be understood that any one or more of the above methods may be utilized as known in the art. Similarly, the semiconductor structure may be transferred to and between one or more process chambers 114, 116, 118, 120, 122, and 124 configured for etching, such as one or more of inductively coupled plasma (ICP) etching, reactive ion etching (RIE), capacitively coupled plasma (CCP) etching, or the like, as well as other etching processes as known in the art.

In embodiments, the substrate may include bulk substrates, epitaxially grown substrates, silicon, silicon germanium (SiGe), silicon on insulator (SOI), silicon germanium on insulator (SGOI), indium antimonide, lead telluride compound, indium arsenide, indium phosphide, and/or gallium arsenide, as well as any one or more substrate materials discussed above, on insulator wafer. As used herein, the term “semiconductor substrate” refers to a substrate in which the entirety of the substrate is comprised of a semiconductor material. The semiconductor substrate may include any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the semiconductor substrate 300 includes a semiconductor material, e.g., silicon (Si), carbon (C), germanium (Ge), silicon germanium (SiGe), germanium tin (GeSn), other semiconductor materials, or any combination thereof. In one or more embodiments, the substrate includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In embodiments, the semiconductor material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

As illustrated in FIG. 3A, structure 300 is provided that contains two or more electrically isolated channels 302 with a feature 303 formed therebetween, which may be a shallow trench isolation, in embodiments. The two or more electrically isolated channels 302 may be formed from any one or more of the substrate materials discussed herein and have a dielectric material 304 formed thereon. In embodiments, suitable dielectric materials may include one or more gate oxides, one or more high k materials, as well as stacks or combinations thereof. In embodiments, the dielectric material 304 may include one or more layers of a gate oxide, a SiO—SiN—SiO stack, a SiO-PolySi-SiO stack, a high k material, or combinations thereof. As illustrated, the dielectric material 304 may be formed over opposed first and second sidewalls 310 of the feature, as well as on bottom wall 311.

FIG. 3A illustrates depositing a liner material 306 over the dielectric material 304 contained on the first and second sidewalls and bottom wall at operation 201. In embodiments, the liner material may be formed directly over the dielectric material 304. In embodiments, the liner material may be one or more materials suitable for initiating, or seeding, selective growth of one or more conductive materials, and that exhibits good etch properties. Furthermore, the liner material 306 may be selected to meet the resistivity and work function requirements of the device in an event that the liner is not fully consumed during deposition of the conductive material. In embodiments, liner materials may include titanium nitride, titanium silicon nitride, titanium aluminide, titanium aluminum nitride, polycrystalline silicon, amorphous silicon, molybdenum nitride, molybdenum silicide, titanium, ruthenium, tungsten, molybdenum, tantalum nitride, tungsten nitride, tungsten silicide, tungsten carbon nitride, tungsten silicon nitride, niobium nitride, titanium aluminum nitride, titanium silicon nitride, tantalum silicon nitride, ruthenium titanium nitride, lanthanum nitride, or a combination thereof. Advantageously, liners according to the present technology may be deposited utilizing one or more non-selective processes, also referred to as conformal deposition processes, such as ALD, or other processes known in the art. Furthermore, as will be discussed in greater detail below, such liner materials also exhibit excellent etch selectivity compared to the surrounding structure. Regardless, in embodiments, liner materials may include titanium nitride, titanium silicon nitride, polycrystalline silicon, amorphous silicon, molybdenum nitride, molybdenum silicide, tantalum nitride, tungsten nitride, niobium nitride, titanium aluminum nitride, titanium silicon nitride, tantalum silicon nitride, ruthenium titanium nitride, lanthanum nitride, or a combination thereof. In further embodiments, liner materials may include titanium nitride, titanium silicon nitride, polycrystalline silicon, amorphous silicon, molybdenum nitride, molybdenum silicide, or a combination thereof. Moreover, in embodiments, the liner comprises titanium nitride, titanium silicon nitride, amorphous silicon, polycrystalline silicon, molybdenum nitride, molybdenum silicide, or a combination thereof.

Nonetheless, in embodiments, the liner material may be deposited at operation 201 at a thickness greater than a traditional seed layer, while still maintaining a significantly greater critical dimension than after formation of the metallic signal or power line. Namely, it may be advantageous to deposit a slightly thicker liner material in the event any damage occurs during the bottom punch process, while also maintaining a small enough thickness to allow for a low aspect ratio and large critical dimension. Thus, in embodiments, the linter material may be deposited a thickness of greater than or about 0.5 nm, such as greater than or about 0.75 nm, greater than or about 1 nm, greater than or about 1.25 nm, greater than or about 1.5 nm, greater than or about 1.75 nm, greater than or about 2 nm, greater than or about 2.25 nm, greater than or about 2.5 nm, greater than or about 2.75 nm, such as greater than or about 3 nm, or such as less than or about 4 nm, less than or about 3.5 nm, less than or about 3 nm, less than or about 2.5 nm, less than or about 2 nm, or any ranges or values therebetween. However, it should be clear that, in embodiments, no liner may be present in the finished device, as the liner may be partially or fully replaced by the conductive material to allow selective deposition of the conductive material.

Regardless of the deposition method selected, the structure illustrated in FIG. 3A, measured with a width between adjacent liner material layers, may have an aspect ratio of less than or about 30:1, such as less than or about 25:1, such as less than or about 20:1, such as less than or about 19:1, less than or about 18:1, less than or about 17:1, less than or about 16:1, less than or about 15:1, less than or about 14:1, less than or about 13:1, less than or about 12:1, less than or about 11:1, such as less than or about 10:1, or any ranges or values therebetween. Thus, the structure illustrated in FIG. 3A may have an advantageous critical dimension (e.g. feature width) as well reduced aspect ratio, as compared to structures having a metallic signal or power line formed over the liner. Such a structure may therefore allow for an easier etch process with reduced damage.

Namely, the intermediate structure may have a critical dimension CD between adjacent sidewalls of greater than or about 4 nm, such as greater than or about 5 nm, such as greater than or about 6 nm, such as greater than or about 7 nm, greater than or about 8 nm, greater than or about 9 nm, greater than or about 10 nm, greater than or about 11 nm, greater than or about 12 nm, greater than or about 13 nm, greater than or about 14 nm, greater than or about 15 nm, greater than or about 16 nm, such as greater than or about 17 nm, such as greater than or about 18 nm, such as greater than or about 19 nm, such as greater than or about 20 nm, such as greater than or about 22 nm, such as greater than or about 24 nm, such as greater than or about 26 nm, such as greater than or about 28 nm, such as up to about 30 nm, or such as less than or about 30 nm, less than or about 28 nm, less than or about 26 nm, less than or about 24 nm, less than or about 22 nm, less than or about 20 nm, less than or about 18 nm, less than or about 16 nm, less than or about 14 nm, less than or about 12 nm, less than or about 10 nm, or any ranges or values therebetween. The CD may also be utilized to measure the width of a unit cell, such as for determining the aspect ratio of the feature prior to deposition of the conductive material.

Thus, as illustrated in FIG. 3B, the liner material may be bottom etched, also referred to as “bottom punched” at operation 202. Surprisingly, by bottom etching the liner material 306 prior to deposition of the conductive material, the process may leave little residue or damage after the bottom etching process. Furthermore, etch chemistry for liner materials is easily tailored to be selective for the liner material. In embodiments, the bottom etching may include a direction etch process, such as a reactive-ion etch, as well as other etching methods as known in the art. Nonetheless, as illustrated, the top portion and at least a portion of the liner disposed on the bottom wall is removed while retaining the liner portion on sidewalls 310. Namely, as illustrated, in embodiments, the bottom etching operation may remove some or all of the liner, namely, remove generally all of the liner disposed in the central critical dimension region, while retaining the portion of the liner that is both disposed on the bottom and adjacent to the sidewalls. Regardless, in embodiments, it should be clear that discrete portions of liner may remain on the bottom wall after deposition.

In embodiments, an optional protective film may be applied over the liner material prior to bottom etching to further protect the liner material. In such embodiments, the protective film may include silicon, silicon oxide, silicon nitride, carbon, titanium, titanium nitride, tungsten nitride, aluminum oxide, or the like, which may be removed after bottom etching. In embodiments, the liner material may instead be deposited at a greater thickness than necessary to minimize the impact of any damage during etching. Moreover, as the liner material serves as a selective deposition surface for the conductive material, low amounts of damage may have little impact on the final structure, as the conductive material will grow over the liner material as long as liner material is present.

After bottom etching at operation 202, the semiconductor structure 300 may optionally undergo one or more cleaning operations, such as an oxide removal, an oxide conversion operation, and/or etching of the exposed surface of the liner material, which may have been altered by air or the bottom punch operation, at optional operation 203. One or more cleaning operations may be utilized to remove any oxides formed during the bottom punch operation, or to convert the oxide back into the liner material (e.g. TiO to TiN).

However, it should be understood that, in embodiments, no cleaning operation(s) may be necessary. For instance, in embodiments, operations 201, 202, and/or 204 may be conducted in the same cluster tool without breaking a vacuum environment. Moreover, in embodiments, one or more conductive materials may be formed from precursors that themselves etch the oxide, and therefore do not utilize an independent cleaning operation. For instance, as will be discussed in greater detail below, the conductive precursor may etch all or a portion of the liner material, replacing a damaged or exposed surface of the liner material without an intervening cleaning operation, or may even fully remove and replace the liner material with the targeted conductive material(s).

Regardless of whether a cleaning operation is conducted, at operation 204, one or more conductive materials 308 may be selectively deposited over the liner material 306, as illustrated in FIG. 3C. As illustrated, in embodiments, the one or more conductive materials may be formed directly on the liner material 306. Furthermore, in embodiments, little to no conductive material may be formed over the exposed dielectric material on the bottom wall. For instance, as discussed above, by carefully selecting the liner material and conductive material, the conductive material may deposit selectively on the liner material without growing on any exposed material other than the liner material. Thus, as the liner material has already undergone bottom etching, the conductive material may selectively deposit along the sidewalls, maintaining separation between adjacent conductive material layers 308 without requiring etching of the conductive material. Stated differently, in embodiments of the present technology, the conductive material, which may be a metallic signal or power line, such as a wordline and/or bitline material in embodiments, may only be formed on a liner material surface even without etching the conductive material. As discussed above, in embodiments, the conductive material 308 may partially or completely remove and/or replace the liner material 306. Regardless, the critical dimension after deposition of the conductive material 308 is reduced from the prior critical dimension prior to deposition of the conductive material, illustrated by CD₂ in FIG. 3C. Thus, in embodiments, the thickness of the liner material and conductive material, which may be all or substantially all conductive material after deposition, is greater than or about 1 nm, such as greater than or about 2 nm, greater than or about 3 nm, greater than or about 3.5 nm, greater than or about 4 nm, greater than or about 4.5 nm, greater than or about 5 nm, greater than or about 5.5 nm, greater than or about 6 nm, greater than or about 6.5 nm, such as greater than or about 7 nm, such as less than or about 14 nm, less than or about 12 nm, less than or about 10 nm, or any ranges or values therebetween.

In embodiments, conductive materials may include any one or more conductive materials, that may also have a conductive in embodiments, capable of selective growth over the liner material selected. In embodiments, conductive materials may include titanium nitride, titanium silicon nitride, polycrystalline silicon, molybdenum nitride, molybdenum silicide, titanium, tantalum, ruthenium, tungsten, molybdenum, platinum, nickel, cobalt, tantalum nitride, tungsten nitride, niobium nitride, titanium aluminide, titanium aluminum nitride, titanium silicide, titanium silicon nitride, tantalum silicide, tantalum silicon nitride, ruthenium titanium nitride, nickel silicide, cobalt silicide, iridium oxide, ruthenium oxide or a combination thereof, and combinations thereof. In embodiments, conductive materials may include one or more metals, such as titanium nitride, molybdenum nitride, molybdenum silicide, titanium, tantalum, ruthenium, tungsten, molybdenum, platinum, nickel, cobalt, tantalum nitride, tungsten nitride, niobium nitride, titanium aluminide, titanium aluminum nitride, titanium silicide, titanium silicon nitride, tantalum silicide, tantalum silicon nitride, ruthenium titanium nitride, nickel silicide, cobalt silicide, iridium oxide, ruthenium oxide or a combination thereof, and combinations thereof. Furthermore, in embodiments, the conductive material may include titanium nitride, molybdenum nitride, titanium, tantalum, ruthenium, tungsten, molybdenum, platinum, nickel, cobalt, tantalum nitride, tungsten nitride, niobium nitride, titanium aluminide, or a combination thereof, and combinations thereof. In further embodiments, the conductive material may include titanium nitride, titanium, tantalum, ruthenium, tungsten, molybdenum, platinum, nickel, cobalt, tungsten nitride, or a combination thereof, and combinations thereof. In embodiments, the conductive material is different than the liner material. Moreover, in embodiments, the conductive material comprises molybdenum, ruthenium, tungsten, titanium nitride, titanium, or a combination thereof.

The conductive material may be selective deposited utilizing one or more processes as known in the art, such as utilizing ALD or CVD processes, in embodiments. Namely, one or more precursors of the selected conductive may be flowed alone, or co-flowed with one or more carrier and/or inert gasses, into the chamber after bottom etching, contacting the etched liner material. For instance, when utilizing molybdenum as the conductive material, suitable precursors may include molybdenum chloride, molybdenum oxychloride, a molybdenum based metal organic compound, or combinations thereof. However, it should be clear that other precursors may be utilized based upon the conductive material selected.

Moreover, as discussed above, the precursor(s) may be selected so as to etch native oxide formed on the liner material, such that an optional cleaning operation may not be necessary. For instance, when utilizing molybdenum as the conductive material, a molybdenum chloride precursor may be introduced which selectively etches the native oxide formed on the liner material. After any oxide present on the liner is etched, the molybdenum chloride will selectively deposit on the liner material. As a further example, when utilizing tungsten as the conductive material, a tungsten chloride precursor may be introduced which selectively etches the native oxide formed on the liner material. After any oxide present on the liner is etched, the tungsten chloride will selectively deposit on the liner material. Thus, the precursor material(s) may be selected to reduce the need for one or more cleaning operations.

The deposition may be conducted at a temperature of greater than or about 200° C., such as greater than or about 210° C., such as greater than or about 220° C., such as greater than or about 230° C., such as greater than or about 240° C., such as greater than or about 250° C., such as greater than or about 260° C., such as greater than or about 270° C., such as greater than or about 280° C., such as greater than or about 290° C., such as greater than or about 300° C., such as greater than or about 310° C., such as greater than or about 320° C., such as greater than or about 330° C., such as greater than or about 340° C., such as greater than or about 350° C., such as greater than or about 360° C., such as greater than or about 370° C., such as greater than or about 380° C., such as greater than or about 390° C., such as greater than or about 400° C., such as greater than or about 410° C., such as greater than or about 420° C., such as greater than or about 430° C., such as greater than or about 440° C., such as greater than or about 450° C., such as greater than or about 460° C., such as greater than or about 470° C., such as greater than or about 480° C., such as greater than or about 490° C., such as greater than or about 500° C., such as greater than or about 510° C., such as greater than or about 520° C., such as greater than or about 530° C., such as greater than or about 540° C., such as greater than or about 550° C., or any ranges or values therebetween. Furthermore, it should be understood that the temperature or other chamber process conditions may be selected based upon the precursor(s) selected and/or the desired conductive material.

Furthermore, in embodiments, the conductive material may deposited at a chamber pressure of greater than or about 50 millitorr, such as greater than or about 500 millitorr, such as greater than or about 1 torr, such as greater than or about 5 torr, such as greater than or about 10 torr, such as greater than or about 15 torr, such as greater than or about 20 torr, such as greater than or about 25 torr, such as greater than or about 30 torr, such as greater than or about 35 torr, such as greater than or about 40 torr, such as greater than or about 45 torr, such as greater than or about 50 torr, such as greater than or about 75 torr, such as greater than or about 100 torr, such as greater than or about 150 torr, such as greater than or about 200 torr, such as greater than or about 250 torr, such as greater than or about 300 torr, such as greater than or about 350 torr, such as greater than or about 400 torr, such as greater than or about 450 torr, such as greater than or about 500 torr, such as greater than or about 550 torr, such a greater than or about 600 torr, such as greater than or about 650 torr, such as greater than or about 700 torr, up to about 760 torr, or any ranges or values therebetween.

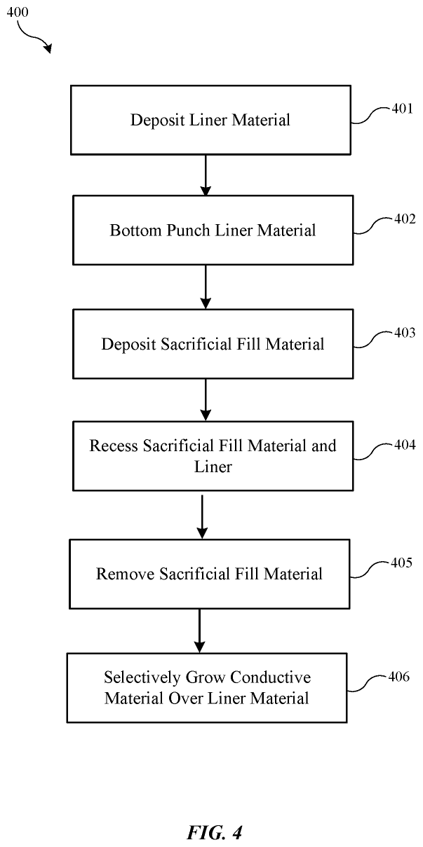

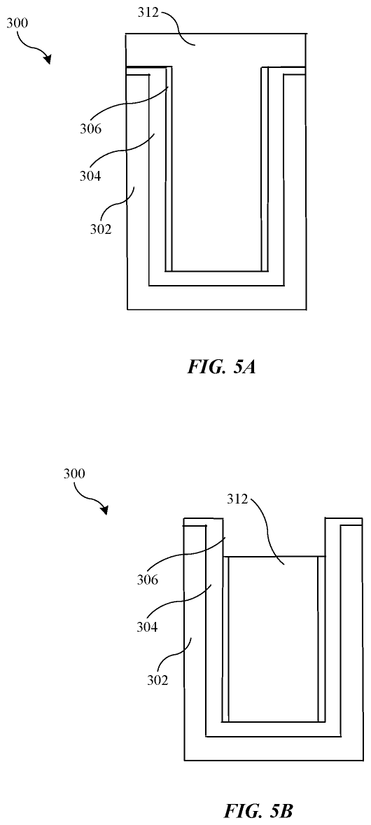

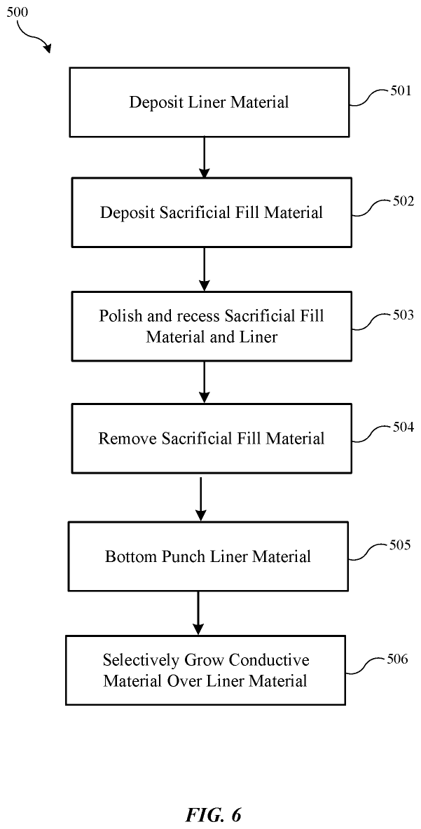

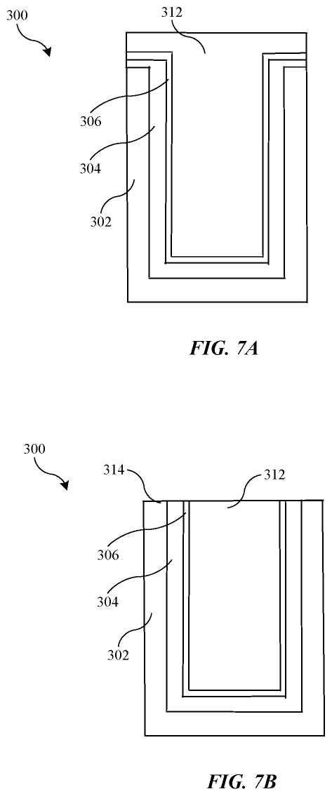

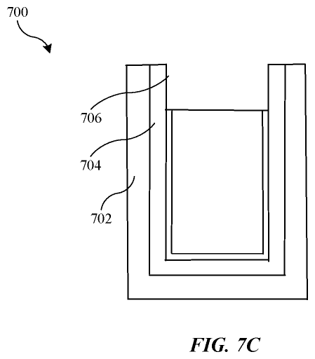

Regardless of the process conditions utilized, as illustrated in FIG. 3D, in embodiments, the liner material and/or conductive material are etched back to the desired gate length. However, one or more methods may be utilized to perform such etching without taking away from the processes discussed herein allowing for formation of the conductive materials on the feature sidewall but not on a feature bottom wall, without requiring etching of the conductive material. FIGS. 4 and 6 may illustrate process steps for forming such a gate length, which may be discussed in conjunction with FIGS. 5A-5B and 7A-7C. However, it should be understood that still further methods may be utilized for forming the semiconductor structures discussed herein. Namely, while FIGS. 3C and 3D illustrate deposition prior to gate length recessing, it should be clear that the liner material may be recessed prior to deposition of the conductive material.

FIG. 4 shows exemplary operations in a method 400 according to some embodiments of the present technology. The method may be performed in a variety of processing chambers, including processing chamber 100 described above. Method 400 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. In addition, while the method may describe the formation method vertically, it should be understood that the other orientation from bit line to word line side may be utilized.

In embodiments, operations 401 and 402 may be conducted according to any one or more of the embodiments discussed above in regards to operations 201 and 202. However, as illustrated in FIG. 5A, at operation 403, a sacrificial material 312 may be filled into the feature. While not shown, it should be understood that, in embodiments, the conductive material 308 may be formed over liner material 306 prior to operation 404. In embodiments, the sacrificial material may be any one or more materials having etch selectivity to oxide material 304.

Nonetheless, FIG. 5B illustrates operation 404, where the sacrificial material and the liner material (and the conductive material, if present) are recessed to the desired depth based upon the target gate length. While a single step etch process is illustrated, where the sacrificial material and the liner material are etched simultaneously, it should be understood that a multi-step operation is also contemplated herein. Namely, in such embodiments, the sacrificial material may be initially recessed to a desired depth, and then the liner material is recessed. In addition, while not shown, it should be understood that, in embodiments, an etch back and/or a chemical mechanical polishing operation may be conducted to remove the sacrificial material and liner material from a top surface of the semiconductor structure prior to recessing the sacrificial material and liner material. The recessing operation may be conducted by any etching processes as known in the art.

After recessing the sacrificial material and the liner material (and the conductive material, if present), the remaining sacrificial material may be removed at operation 405, and the semiconductor structure may re-enter the process flow discussed above in regards to FIG. 3C and operations 203 and 204. However, as discussed above, in embodiments, the conductive material may have been formed over the liner material prior to introduction of the sacrificial material.

FIG. 6 shows exemplary operations in a method 500 according to some embodiments of the present technology. The method may be performed in a variety of processing chambers, including processing chamber 100 described above. Method 500 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. In addition, while the method may describe the formation method vertically, it should be understood that the other orientation from bit line to word line side may be utilized.

In embodiments, operation 501 may be conducted according to any one or more of the embodiments discussed above in regards to operation 201. However, as illustrated in FIG. 7A, at operation 502, a sacrificial material 312 may be filled into the feature. FIG. 7B illustrates an etch back and/or a chemical mechanical polishing portion of operation 503, where the liner material 306 and sacrificial material 312 are polished from a top surface 314 of the semiconductor structure.

Nonetheless, FIG. 7C illustrates recessing at operation 503, where the sacrificial material and the liner material are recessed to the desired depth based upon the target gate length. While a single step etch process is illustrated, where the sacrificial material and the liner material are etched simultaneously, it should be understood that a multi-step operation is also contemplated herein. Namely, in such embodiments, the sacrificial material may be initially recessed to a desired depth, and then the liner material is recessed. The recessing operation may be conducted by any etching processes as known in the art.

After recessing the sacrificial material and the liner material (and the conductive material, if present), the remaining sacrificial material may be removed at operation 504, and the semiconductor structure may re-enter the process flow discussed above in regards to FIGS. 3B and 3C and operations 202-204. Namely, the liner material may undergo bottom punching at operation 505, optional cleaning, and selective growth of the conductive material at operation 506, according to any one or more of the embodiments discussed above.

It should be appreciated that the specific steps illustrated in the figures provide particular methods of forming 4F² DRAM arrays according to various embodiments, but are also applicable to other advanced memory structures as discussed herein. Other sequences of steps may also be performed according to alternative embodiments. For example, alternative embodiments may perform the steps outlined above in a different order. Moreover, the individual steps illustrated in the figures may include multiple sub-steps that may be performed in various sequences as appropriate to the individual step. Furthermore, additional steps may be added or removed depending on the particular applications. Many variations, modifications, and alternatives also fall within the scope of this disclosure.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A method of forming an advanced memory device, comprising:
forming a dielectric material layer over a first sidewall, a second sidewall, and a bottom wall, of one or more features, wherein the first sidewall is spaced apart from the second sidewall and the bottom wall is disposed between the first sidewall and the second sidewall;
depositing a liner material directly on the dielectric material layer on the first sidewall, the second sidewall, and the bottom wall;
removing at least a portion of the liner material from the bottom wall; and
selectively depositing a conductive material on a remaining portion of the liner material.

2. The method of claim 1, wherein the liner material is deposited conformally on the first sidewall and the second sidewall.

3. The method of claim 1, wherein the liner material is deposited by an atomic layer deposition process, a chemical vapor deposition process, or a combination thereof.

4. The method of claim 1 wherein the conductive material is deposited utilizing a selective atomic layer deposition process, a selective chemical vapor deposition process, or a combination thereof.

5. The method of claim 1, wherein the conductive material is only deposited over the liner material.

6. The method of claim 1, wherein depositing the liner material, removing the portion of the liner material, and depositing the conductive material are conducted without a vacuum break.

7. The method of claim 1, further comprising recessing the liner material.

8. The method of claim 7, wherein the conductive material is recessed with the liner material, or is selectively deposited on the remaining portion of the liner material after recessing the liner material.

9. The method of claim 1, further comprising filling the one or more features with a sacrificial material after depositing the liner material.

10. The method of claim 9, wherein recessing the liner material is conducted prior to filling the one or more features.

11. The method of claim 9, wherein the liner material is recessed simultaneously or sequentially with the sacrificial material.

12. The method of claim 1, wherein the liner material comprises titanium nitride, titanium silicon nitride, titanium aluminide, titanium aluminum nitride, polycrystalline silicon, amorphous silicon, molybdenum nitride, molybdenum silicide, titanium, ruthenium, tungsten, molybdenum, tantalum nitride, tungsten nitride, tungsten silicide, tungsten carbon nitride, tungsten silicon nitride, niobium nitride, titanium aluminum nitride, titanium silicon nitride, tantalum silicon nitride, ruthenium titanium nitride, lanthanum nitride, or a combination thereof.

13. The method of claim 1, wherein the conductive material comprises titanium nitride, titanium silicon nitride, polycrystalline silicon, molybdenum nitride, molybdenum silicide, titanium, tantalum, ruthenium, tungsten, molybdenum, platinum, nickel, cobalt, tantalum nitride, tungsten nitride, niobium nitride, titanium aluminide, titanium aluminum nitride, titanium silicide, titanium silicon nitride, tantalum silicide, tantalum silicon nitride, ruthenium titanium nitride, nickel silicide, cobalt silicide, iridium oxide, ruthenium oxide or a combination thereof, and combinations thereof.

14. The method of claim 13, wherein the conductive material comprises molybdenum, tungsten, or a combination thereof, and wherein the molybdenum and/or tungsten is selectively deposited by contacting the liner material with one or more molybdenum and/or tungsten precursors.

15. The method of claim 14, wherein the one or more molybdenum precursors comprises molybdenum chloride, molybdenum oxychloride, a molybdenum based metal organic compound, or a combination thereof, and/or the one or more tungsten precursors comprises tungsten chloride.

16. An advanced memory array, comprising:
a feature having a first sidewall opposed to a second sidewall, and a bottom wall;
a dielectric material layer formed over the first sidewall, second sidewall, and the bottom wall;
a liner formed over the dielectric material layer on the first sidewall, second sidewall and the bottom wall; and
a conductive material formed over the liner on the first sidewall and the second sidewall, wherein the bottom wall is generally free of the conductive material, and wherein the conductive material formed over the liner on the first sidewall is electrically separated from the conductive material formed over the liner on the second sidewall;
wherein the conductive material comprises molybdenum, ruthenium, tungsten, titanium nitride, titanium, or a combination thereof, and the liner comprises titanium nitride, titanium silicon nitride, amorphous silicon, polycrystalline silicon, molybdenum nitride, molybdenum silicide, or a combination thereof.

17. The array of claim 16, wherein an aspect ratio of the feature, having a width measured from the liner material, is less than or about 20:1.

18. A semiconductor processing system, comprising:
a system controller configured to
form a dielectric material layer over a first sidewall, second sidewall, and a bottom wall of a feature, in a first processing chamber,
deposit a liner material over the dielectric material layer on the first sidewall, second sidewall, and bottom wall, in a second processing chamber,
etch the liner material from the bottom wall, in a third processing chamber, and
selectively deposit a conductive material over the liner material, in the second processing chamber or in a fourth processing chamber.

19. The semiconductor processing system of claim 18, wherein the second processing chamber, third processing chamber, and optional fourth processing chamber, are contained within a cluster tool having a shared vacuum environment.

20. The semiconductor processing system of claim 18, further comprising a further processing chamber comprising one or more oxide removal systems.
